(19) United States
(12) Patent Application Publication
(10) Pub. No.: US 2026/0172155 A1
(43) Pub. Date: Jun. 18, 2026

(54) CYCLE COUNTING CIRCUIT

(71) Applicant: Kioxia Corporation, Tokyo (JP)

(72) Inventor: Mikio SHIRAISHI, Yokohama Kanagawa (JP)

(21) Appl. No.: 19/319,650

(22) Filed: Sep. 4, 2025

(30) Foreign Application Priority Data
Dec. 18, 2024 (JP) 2024-221806

(51) Int. Cl. H04L 1/24

(52) U.S. Cl. CPC H04L 1/24

(57) ABSTRACT

A cycle counting circuit counts the number of cycles of a bit stream that has a cycle of 2^{k}−1 bits, and is output in units of n bits. A first counter operates as a (p+1)-ary counter (where p represents a quotient, 2^{k}−1 a dividend, and n a divisor) and a p-ary counter, respectively, while selection signals of first and second levels are being received, counts clock cycles to acquire a first count, and outputs a first signal when the first count reaches p and p−1 while the first counter is operating as the (p+1)-ary counter and the p-ary counter, respectively. A second counter and an n-ary counter each count occurrences of the first signal to acquire second and third counts, respectively. A comparison circuit outputs the first-level selection signal while the third count is less than r (r is a remainder of the division), and the second-level selection signal otherwise.

### CROSS-REFERENCE TO RELATED APPLICATION(S)

This application is based upon and claims the benefit of priority from Japanese Patent Application No. 2024-221806, filed Dec. 18, 2024, the entire contents of which are incorporated herein by reference.

### FIELD

Embodiments described herein relate generally to a cycle counting circuit.

### BACKGROUND

A communication apparatus may include a pseudo random binary sequence (PRBS) generator circuit for measurement and calibration of a certain index. Examples of such an index include a bit error rate of the communication apparatus, and examples of a calibration target include a coefficient of a waveform equalizer built into the communication apparatus. The PRBS has a cycle that is determined based on a mechanism of generating the PRBS. That is, the same PRBS is generated for every certain cycle. In the process of the measurement and/or the calibration, the number of cycles, that is, the cycle count is counted. A cycle counting circuit for counting the number of cycles can be built into the communication apparatus.

### BRIEF DESCRIPTION OF THE DRAWINGS

FIG. 1 is a block diagram illustrating a system including a cycle counting circuit according to a first embodiment.

FIG. 2 is a block diagram illustrating the cycle counting circuit and a PRBS generator circuit according to the first embodiment.

FIG. 3 is a diagram illustrating an example of a generated PRBS.

FIG. 4 is a diagram illustrating transition of errors of count values of cycles in the first embodiment and, for comparison and reference, in a first type method.

FIG. 5 is a block diagram illustrating a cycle counting circuit and a PRBS generator circuit according to a second embodiment.

FIG. 6 is a block diagram illustrating a cycle counting circuit and a PRBS generator circuit according to a third embodiment.

FIG. 7 is a block diagram illustrating a cycle counting circuit and a PRBS generator circuit according to a fourth embodiment.

FIG. 8 is a block diagram illustrating a cycle counting circuit and a PRBS generator circuit according to a fifth embodiment.

FIG. 9 is a block diagram illustrating a cycle counting circuit and a PRBS generator circuit according to a sixth embodiment.

FIG. 10 is a block diagram illustrating a cycle counting circuit and a PRBS generator circuit according to a seventh embodiment.

### DETAILED DESCRIPTION

Embodiments provide a cycle counting circuit that can count the number of cycles with smaller errors.

In general, according to one embodiment, a cycle counting circuit counts the number of cycles of a bit stream that has a cycle of 2^{k}−1 bits (where k is a positive integer) bits, and is output in units of n bits (where n is a positive integer) in synchronization with a clock, and includes a first counter, a second counter, an n-ary counter, and a comparison circuit. The first counter is configured to operate as a (p+1)-ary counter (where p is a quotient of a division in which a 2^{k}−1 is a dividend and n is a divisor) while a selection signal of a first level is being received, to operate as a p-ary counter while the selection signal of a second level is being received, to count clock cycles to acquire a first count value, and to output a first signal of a third level when the first count value reaches p while the first counter is operating as the (p+1)-ary counter and when the first count value reaches p−1 while the first counter is operating as the p-ary counter. The second counter is configured to count occurrences of the first signal at the third level to acquire a second count value and to output a first bit stream representing the second count value. The n-ary counter is configured to count occurrences of the first signal at the third level to acquire a third count value and to output a second bit stream representing the third count value. The comparison circuit is configured to output the selection signal of the first level while the third count value is less than r (where r is a remainder of the division) and to output the selection signal of the second level while the third count value is r or more.

Hereinafter, embodiments will be described with reference to the drawings. In order to distinguish between a plurality of components having substantially the same function and configuration in a certain embodiment or different embodiments, numbers or characters may be added to the ends of reference numerals. In the description of an embodiment following a certain described embodiment, differences from the described embodiment will be mainly described. All the description of the already described embodiment will apply to the description of other embodiments unless explicitly or obviously excluded.

In the present specification and the claims, a certain first element being “connected to” another second element also includes the first element being connected to the second element directly, constantly, or selectively through a conductive element.

### 1. First Embodiment

### 1.1. Configuration

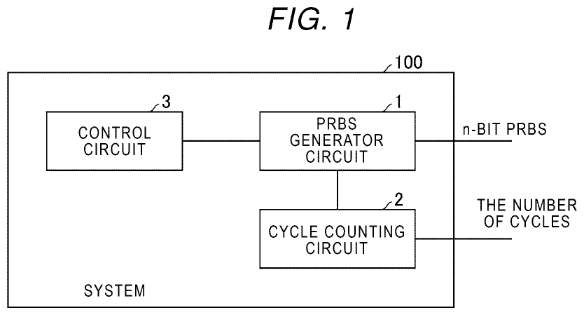

FIG. 1 is a block diagram illustrating a system 100 including a cycle counting circuit according to a first embodiment. The system 100 may be provided in a communication apparatus.

As illustrated in FIG. 1, the system 100 includes a PRBS generator circuit 1, a cycle counting circuit 2, and a control circuit 3.

The control circuit 3 controls the PRBS generator circuit 1. The control circuit 3 outputs a clock CK and a reset signal RN.

The PRBS generator circuit 1 is a circuit that generates the PRBS. The PRBS generator circuit 1 is a parallel type and outputs an n-bit PRBS. The n-bit PRBS described herein is obtained by dividing a PRBS that is a binary sequence for every n bits. As the PRBS generator circuit, a tandem type and a parallel type are known. The tandem type PRBS generator circuit outputs a 1-bit PRBS in synchronization with an edge (for example, rise) of a clock. The parallel type PRBS generator circuit 1 outputs an n-bit PRBS in synchronization with an edge (for example, rise) of a clock.

A method or algorithm of generating the PRBS may be any method or algorithm. For example, the PRBS generator circuit 1 may be a linear feedback shift register (LFSR). In other examples, the PRBS generator circuit 1 generates the PRBS using a Lagged Fibonacci method, a method described in U.S. Pat. No. 10,884,706, a method described in Donald E. Knuth, “The Art of Computer Programming Volume 2 Seminumerical Algorithms Third Edition, Japanese Edition”, Third Chapter, Xorshift, a method described in US Patent Application Publication No. 2024/061590, or a Mersenne Twister method.

The cycle counting circuit 2 is a circuit that counts the number of cycles of the PRBS, that is, how many cycles of the PRBS are generated by the PRBS generator circuit 1. Unlike a completely random signal, the PRBS has a certain cycle, in which the same bit pattern is repeated every one cycle. The cycle of the PRBS does not change irrespective of whether the generation method is a tandem type or a parallel type. However, in general, the cycle of the PRBS is not a multiple of the bit width n that is used in the parallel type generation method. In the tandem type, for example, by counting a clock used for the generation, the PRBS cycle can be measured, and the number of cycles can be acquired from the measurement result. Meanwhile, in the parallel type, even when the clock used for the generation is counted, the PRBS cycle can be measured as only a multiple of n, and efforts are required to determine the number of cycles.

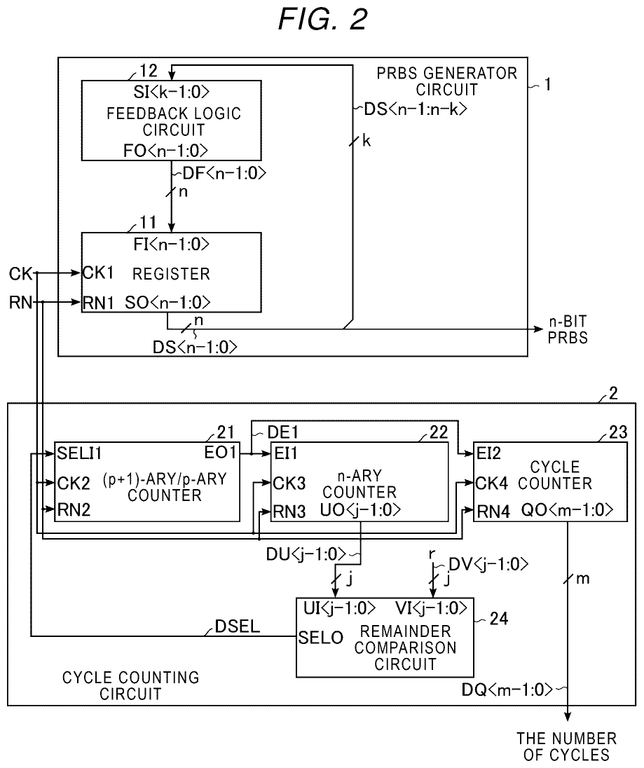

FIG. 2 is a block diagram illustrating the cycle counting circuit and a PRBS generator circuit according to the first embodiment. As described above with reference to FIG. 1, the PRBS generator circuit 1 may generate the PRBS using any method or algorithm. For example, the PRBS generator circuit 1 includes a register 11 and a feedback logic circuit 12. The following description is based on this example.

The register 11 is a circuit that temporarily stores an n-bit stream, where n is a positive integer. The register 11 includes n input terminals FI <n−1:0>, n output terminals SO <n−1:0>, a clock input terminal CK1, and a reset signal input terminal RN1. The notation, terminal α<β:γ>, means a set including (β−γ+1) terminals α_γ, α_γ+1, . . . , and α_β.

The register 11 stores a bit stream input to the register 11, and outputs the stored bit stream. The register 11 receives the reset signal RN at the reset signal input terminal RN1. When the reset signal RN of a level corresponding to a reset instruction, is received, the register 11 resets the stored bit stream to a predetermined initial value. The register 11 operates while the reset signal RN of a level that does not correspond to the reset instruction, is being received. For example, the reset signal RN instructs the register 11 to reset when it is at a low level, and instructs the register 11 to operate when it is at a high level. The following description is based on this example.

The register 11 receives a bit stream DF <n−1:0> at each of the input terminals FI <n−1:0>. A bit stream and a bit are transmitted through a signal. That is, reception of a bit or bit stream is the same as reception of a signal through which the bit or bit stream is transmitted, and output of a bit or bit stream is the same as output of a signal through which the bit or bit stream is transmitted. The notation “bit stream δ<β:γ>” means that a bit stream δ has a width of (β−γ+1) bits and includes bits δ_γ, δ_γ+1, δ_γ+2, . . . , δ_β−1, and δ_β. The bit δ_β transmits the most significant (or the β-rank) bit of the bit stream δ<β:γ>. The bit δ_γ transmits the least significant (or the γ-rank) bit of the bit stream δ<β:γ>. A bit δ_Z is located at a more significant position in the bit stream δ<β:γ> as Z increases.

The register 11 outputs a bit stream DS <n−1:0> stored in the register 11 at each of the output terminals SO <n−1:0>. The bit stream DS <n−1:0> functions as the output of the PRBS generator circuit 1, that is, the n-bit PRBS. The number of bits of the PRBS, that is, n bits are defined as one word of the PRBS. The numerical value n will also be referred to as the number of bits n.

The register 11 receives the clock CK at the clock input terminal CK1. The register 11 outputs the bit stream DS <n−1:0> in synchronization with the edge (for example, rise) of the clock CK.

The feedback logic circuit 12 includes k input terminals SI <k−1:0> and n output terminals FO <n−1:0>. k represents the order of the term of power of 2 in the expression 2^{k}−1 representing the cycle of the PRBS, and represents a positive integer of less than n. k will also be simply referred to as the order of the PRBS. The feedback logic circuit 12 receives a bit stream DS <n−1:n−k> at each of the input terminals SI <k−1:0>. The bit stream DS <n−1:n−k> contains continuous k bits including the most significant bit in the bit stream DS <n−1:0>. The feedback logic circuit 12 generates the bit stream DF <n−1:0> from the bit stream DS <n−1:n−k>. Any generation method may be used. That is, the method of generation is based on the method of generating the PRBS using the PRBS generator circuit 1.

The feedback logic circuit 12 outputs the bit stream DF <n−1:0> at each of the n output terminals FO <n−1:0>.

The cycle counting circuit 2 counts the number of cycles of the PRBS. As described above, typically, the cycle of the PRBS is not divisible by n. Therefore, after the first bit of the PRBS appears in any bit of the bit stream DS <n−1:0> that is the output of the PRBS generator circuit 1, when the first bit of the PRBS appears again in any bit (in general, the bit position is different from the previous one) of the DS <n−1:0>, this is considered one cycle of the PRBS.

In the tandem type PRBS generator circuit, the cycle 2^{k}−1 of the generated k-order PRBS is the same as the number of rising edges of the clock required for the generation. That is, the 2^{k}−1 bit pattern is generated for every one bit. Accordingly, the number of times of rising of the clock CK is measured by a (2^{k}−1)-ary counter such that the number of cycles is easily counted. To that end, the number of cycles is increased by 1 each time the value of the (2^{k}−1)-ary counter reaches its maximum. Hereinafter, this method of counting the number of cycles will be referred to as the first type method for comparison and reference.

In the first type method, the (2^{k}−1)-ary counter needs to operate for every rising of the clock. In addition, depending on the size of k, the area of the (2^{k}−1)-ary counter is large. As the operation of the communication apparatus becomes faster, a modulation method where the run length of continuous bits of 0 or 1 is long in modulated data from the perspective of improving the transmission efficiency, is adopted. In order to secure the run length of a test pattern corresponding to the modulation method, k tends to increase. In order to deal with the increase in k, a second type is considered. The PRBS has a property in which any continuous k bits in one cycle does not appear again in the same cycle. When a ring is formed by connecting the first and last bits of one cycle of the PRBS, any continuous k bits in this ring are different from any other continuous k bits. Using this property, in the second type, one certain k-bit pattern (for example, that is finally generated) in one cycle of the PRBS is stored in advance as a fixed pattern, and continuous k bits of the PRBS newly generated for every one bit are compared to the above-described fixed pattern, for example, by being stored in a shift register. When the continuous k bits of the newly generated PRBS matches the above-described fixed pattern, the number of cycles is increased by 1.

However, as described below in detail, when the method used in the tandem type is applied to the parallel type such as the PRBS generator circuit 1, the number of cycles is not appropriately counted. As described above, the parallel type PRBS generator circuit 1 generates the PRBS for every n bits. Assuming that a quotient is p and a remainder is r when the cycle 2^{k}−1 of the PRBS is divided by n, the cycle of the PRBS is represented by Expression 1.

$${2}^{k} - 1 = np + r \qquad ( Expression 1 )$$

Expression 2 is satisfied based on the rule of the division.

$$0 \leq r < n \qquad ( Expression 2 )$$

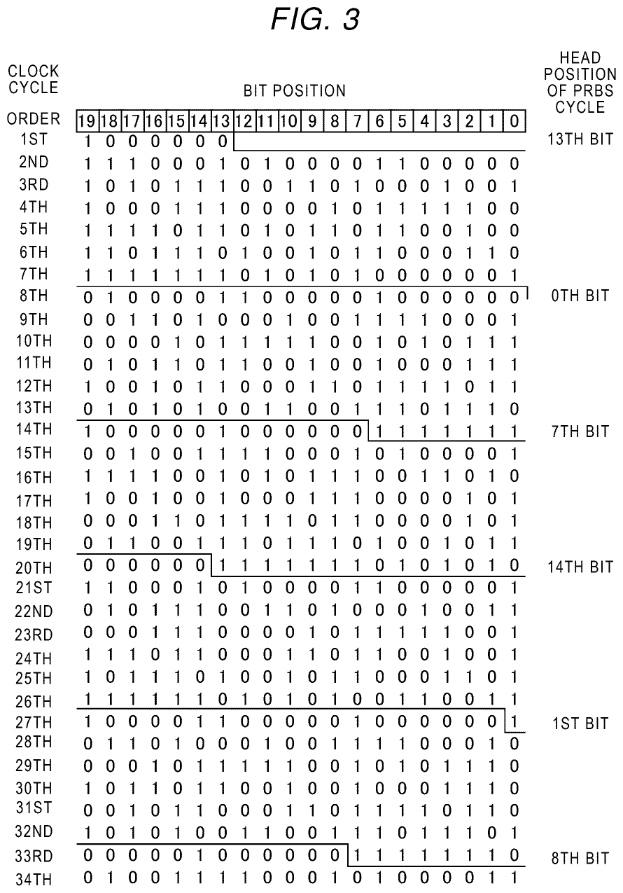

When the cycle of the generated PRBS is counted by a counter as in the first type method, a (p+1)-ary counter is used instead of the (2^{k}−1)-ary counter used in the first type method. The reason for this is that, when the p-ary counter is used, the number of cycles increases while the cycle is not completed. However, when the (p+1)-ary counter is used, errors occur in the counting of the cycle as described below in detail. FIG. 3 illustrates an example of a PRBS generated using a certain method where k=7 and n=20. In this example, p=6 and r=7. FIG. 3 shows the first clock cycle to the 34th clock cycle. The first clock cycle is a period until the clock CK rises first after the register 11 is reset. Hereinafter, a period until the next clock rises is counted as the second clock cycle, the third clock cycle, and the like.

In the example of FIG. 3, the PRBS generated for every n bits is arranged and generated in order from the least significant bit to the most significant bit. The head of the PRBS in the first clock cycle is the 13th bit. The reason for this is as follows. The 0th bit to the 12th bit are not input to the feedback logic circuit 12. Therefore, even when any values are set, there is no influence on the operations in and after the second clock cycle, and thus the 0th bit to the 12th bit can be set to any value. Typically, all of the 0th bit to the 12th bit are reset to 0 and are generated for every one bit, which is treated as delay of the 13 bits.

In FIG. 3, the clock cycle and the bit position in the head of each of the cycles of the PRBS are, for example, as follows.
The first clock cycle: the 13th bit
The eighth clock cycle: the 0th bit
The 14th clock cycle: the seventh bit
The 20th clock cycle: the 14th bit
The 27th clock cycle: the first bit
The 33rd clock cycle: the eighth bit

In this example, when the number of cycles of the PRBS is counted assuming that a (p+1) cycle of the clock CK is one cycle of the PRBS, errors of 13 (=n−r) bits occur for every counting. Therefore, errors are accumulated for every counting, and thus a difference between the actual number of cycles of the PRBS and the number of cycles of the PRBS counted using the (p+1)-ary counter increases. For example, when the counting is performed ten times using the (p+1)-ary counter, errors of 130 bits occur, which exceed one cycle (=2^{k}−1) of the PRBS. In the example of FIG. 3, the bit width n=20 of one word of the PRBS and the cycle 2^{k}−1=127 thereof are coprime. Therefore, a specific word appears only for 20 cycles of the PRBS. Accordingly, the counting using the second type can be performed only on a 20-cycle basis, and the range of counting errors affects the 0th to 19th cycle. The cycle counting circuit 2 deals with the occurrence of the errors.

Referring back to FIG. 2, further description is made. The cycle counting circuit 2 includes a (p+1)-ary/p-ary counter 21, an n-ary counter 22, a cycle counter 23, and a remainder comparison circuit 24.

The (p+1)-ary/p-ary counter 21 is a circuit that counts edges of the supplied clock and outputs a bit stream representing the counting result (count value). The (p+1)-ary/p-ary counter 21 includes a select input terminal SELI1, an enable output terminal EO1, a clock input terminal CK2, and a reset signal input terminal RN2.

The (p+1)-ary/p-ary counter 21 operates as a dynamically selected counter among the (p+1)-ary counter and the p-ary counter. The (p+1)-ary/p-ary counter 21 operates as the (p+1)-ary counter while a signal DSEL of a certain digital level (for example, a low level) is being received at the select input terminal SELI1. The (p+1)-ary/p-ary counter 21 operates as the p-ary counter while the signal DSEL of another digital level (for example, a high level) is being received at the select input terminal SELI1. For example, the signal DSEL instructs the operation as the (p+1)-ary counter using the low level, and instructs the operation as the p-ary counter using the high level. The following description is based on this example.

The (p+1)-ary/p-ary counter 21 receives the clock CK at the clock input terminal CK2. The (p+1)-ary/p-ary counter 21 counts edges (for example, rises) of the received clock CK. While the (p+1)-ary/p-ary counter 21 is operating as the (p+1)-ary counter, the count value has any value of 0 or more and p or less. While the (p+1)-ary/p-ary counter 21 is operating as the p-ary counter, the count value has any value of 0 or more and p−1 or less.

When the count value reaches the upper limit, the (p+1)-ary/p-ary counter 21 outputs an enable signal DE1 of a level representing that the count value reaches the upper limit at the enable output terminal EO1. That is, when the count value reaches p while the (p+1)-ary/p-ary counter 21 is operating as the (p+1)-ary counter, the (p+1)-ary/p-ary counter 21 outputs the enable signal DE1 of the level representing that the count value reaches the upper limit. For example, the level representing that the count value reaches the upper limit is a high level. The following description is based on this example. When the count value reaches p−1 while the (p+1)-ary/p-ary counter 21 is operating as the p-ary counter, the (p+1)-ary/p-ary counter 21 outputs the enable signal DE1 of the high level. When the count value reaches the upper limit, the (p+1)-ary/p-ary counter 21 resets the count value to 0 at a timing of the first rising of the clock CK after the count value reaches the upper limit.

The (p+1)-ary/p-ary counter 21 receives the reset signal RN at the reset signal input terminal RN2. When the reset signal RN of the low level is received, the (p+1)-ary/p-ary counter 21 resets the count value to 0. The (p+1)-ary/p-ary counter 21 performs the counting while the reset signal RN of the high level is being received.

The n-ary counter 22 is a circuit that counts edges of the supplied clock and outputs a bit stream representing the count value. The n-ary counter 22 includes an enable input terminal EI1, j output terminals UO <j−1:0>, a clock input terminal CK3, and a reset signal input terminal RN3.

The n-ary counter 22 receives the enable signal DE1 at the enable input terminal EI1, and receives the clock CK at the clock input terminal CK3. The n-ary counter 22 counts rising edges of the clock CK only while the enable signal DE1 of the high level is being received. The n-ary counter 22 does not perform the counting while the enable signal DE1 of the low level is being received. The n-ary counter 22 outputs a bit stream DU <j−1:0> representing the count value at the output terminals UO <j−1:0>. The count value has any value of 0 or more and n−1 or less. When the count value reaches the upper limit (that is, n−1), the n-ary counter 22 resets the count value to 0 at a timing of the first rising of the clock CK in a period where the enable signal DE1 of the high level is being received after the count value reaches the upper limit.

The n-ary counter 22 receives the reset signal RN at the reset signal input terminal RN3. When the reset signal RN of the low level is received, the n-ary counter 22 resets the count value to 0 irrespective of the value of the enable signal DE1. The n-ary counter 22 performs the counting based on the value of the enable signal DE1 while the reset signal RN of the high level is being received.

The cycle counter 23 is a circuit that counts edges of the supplied clock and outputs a bit stream representing the count value. The cycle counter 23 includes an enable input terminal EI2, m output terminals QO <m−1:0>, a clock input terminal CK4, and a reset signal input terminal RN4.

The cycle counter 23 receives the enable signal DE1 at the enable input terminal EI2, and receives the clock CK at the clock input terminal CK4. The cycle counter 23 counts rising edges of the clock CK only while the enable signal DE1 of the high level is being received. The cycle counter 23 does not perform the counting while the enable signal DE1 of the low level is being received. The cycle counter 23 outputs a bit stream DQ <m−1:0> representing the count value at the output terminals QO <m−1:0>. The count value indicates the number of cycles of the PRBS after transition from the level where the reset signal RN instructs the reset to the level where the reset signal RN does not instruct the reset.

The cycle counter 23 receives the reset signal RN at the reset signal input terminal RN4. When the reset signal RN of the low level is received, the cycle counter 23 resets the count value to 0 irrespective of the value of the enable signal DE1. The cycle counter 23 performs the counting based on the value of the enable signal DE1 while the reset signal RN of the high level is being received.

The remainder comparison circuit 24 is a circuit that outputs a signal of a level based on comparison between the bit streams received at the two input terminals. The remainder comparison circuit 24 includes j input terminals UI <j−1:0>, j input terminals VI <j−1:0>, and an output terminal SELO.

The remainder comparison circuit 24 receives the bit stream DU <j−1:0> at each of the input terminals UI <j−1:0>. The remainder comparison circuit 24 receives a bit stream DV <j−1:0>at each of the input terminals VI <j−1:0>. The bit stream DV <j−1:0> represents a value of a remainder r. For example, the bit stream DV <j−1:0> is supplied from the control circuit 3.

The remainder comparison circuit 24 outputs the signal DSEL at the output terminal SELO. The remainder comparison circuit 24 outputs the signal DSEL of the high level while the value represented by the bit stream DU <j−1:0> is greater than or equal to the value represented by the bit stream DV <j−1:0>. The remainder comparison circuit 24 outputs the signal DSEL of the low level while the value represented by the bit stream DU <j−1:0> is less than the value represented by the bit stream DV <j−1:0>.

### 1.2. Operation

In the PRBS cycle counting operation of the cycle counting circuit 2, the counting where the count value changes from 0 to 1 is the first counting. Then, each time the count value changes, a number is assigned to the counting, such as the second counting and the third counting. Since errors occur in counting, the number of times of counting does not necessarily match the number of cycles of the PRBS. The cycle counting circuit 2 divides the number of times of counting by the number of bits n of the output word of the PRBS generator circuit 1, and operates by further dividing the number of times n into a set containing the first counting to the r-th counting and a set containing the (r+1)th counting to the n-th counting. That is, the (p+1)-ary/p-ary counter 21 functions as the (p+1)-ary counter in a period from the first counting to the r-th counting among the n counting operations. The (p+1)-ary/p-ary counter 21 functions as the p-ary counter in a period from the (r+1)th counting to the n-th counting among the n counting operations. Accordingly, the (p+1)-ary/p-ary counter 21 alternately repeats the (p+1)-ary counting operation r times and the p-ary counting operation (n-r) times. Accordingly, while performing the (p+1)-ary counting operation r times and the p-ary counting operation (n-r) times (that is, while performing the counting n times), the number of rising edges of the clock CK, that is, the number of words w of the PRBS is represented by Expression 3.

$$w = ( p + 1 ) r + p ( n - r ) = np + r \qquad ( Expression 3 )$$

Therefore, the total number of bits of the PRBS output while performing the counting n times is the product of w and n and is represented by Expression 4.

$$nw = n ( np + r ) \qquad ( Expression 4 )$$

The number nw is n times one cycle of the PRBS (PRBS cycle) based on Expression 1. Accordingly, among the n operations of counting the cycle, errors of the cycle count value for the PRBS cycle in the first r counting operations increase in the negative direction for every (n-r) bits, and errors of the cycle count value for the PRBS cycle in the remaining (n-r) counting operations decrease in the positive direction for every r bits. Therefore, errors at the end of the n cycle counting operations are represented by Expression 5.

$$- r ( n - r ) + ( n - r ) r = 0 \qquad ( Expression 5 )$$

That is, whenever the n cycle counting operations end, errors are reset to zero.

### 1.3. Advantageous Effect (Effect)

In the first embodiment, the n-ary counter 22 increases the count value to n by 1 whenever the count value of the (p+1)-ary/p-ary counter 21 reaches the upper limit. The cycle counter 23 increases the cycle count value by 1 whenever the count value of the (p+1)-ary/p-ary counter 21 reaches the upper limit. The remainder comparison circuit 24 causes the (p+1)-ary/p-ary counter 21 to operate as the (p+1)-ary counter while the value represented by the output of the n-ary counter 22 is less than the remainder r, and causes the (p+1)-ary/p-ary counter 21 to operate as the p-ary counter while the value represented by the output of the n-ary counter 22 is the remainder r or more. For every n cycle counting operations, the (p+1)-ary/p-ary counter 21 functions as the (p+1)-ary counter during the first r cycle counting operations, and functions as the p-ary counter during the next (n-r) cycle counting operations. As a result, among the n cycle counting operations, errors of the cycle count value for the PRBS cycle in the first r counting operations increase in the negative direction for every (n-r) bits, and errors of the cycle count value for the PRBS cycle in the remaining (n-r) counting operations decrease in the positive direction for every r bits. Accordingly, whenever the n cycle counting operations end, errors of the cycle count value are reset to zero. That is, the cycle counting circuit 2 can count cycles with smaller errors.

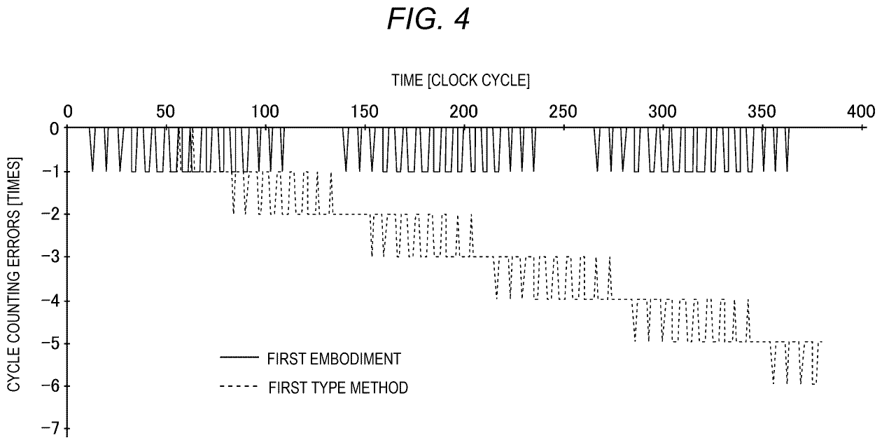

FIG. 4 is a diagram illustrating transition of errors of count values of cycles in the first embodiment and, for comparison and reference, in the first type method. In FIG. 4, the first type method is indicated by a broken line, and the first embodiment is indicated by a solid line.

As illustrated in FIG. 4, a difference between the first embodiment and the first type method is not observed during the initial period after the operation start. However, in the first type method, errors increase in the negative direction over time. On the other hand, in the first embodiment, errors are within a range of 0 to −1 even during the initial period.

### 2. Second Embodiment

A second embodiment is different from the first embodiment in a method of detecting the cycle. The second embodiment relates to a case where r (remainder) is k (the order of the PRBS) or more.

### 2.1. Configuration

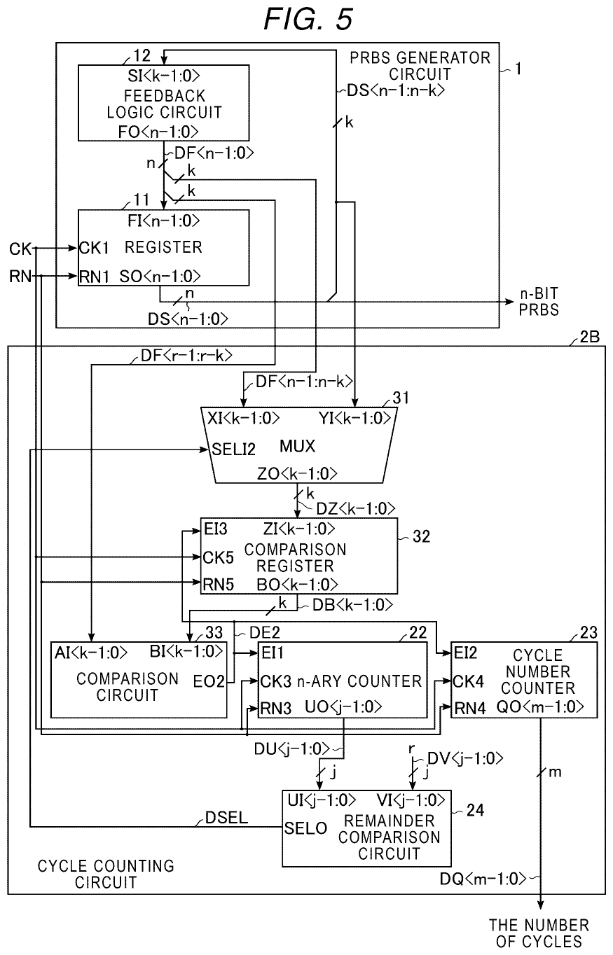

FIG. 5 is a block diagram illustrating a cycle counting circuit and a PRBS generator circuit according to the second embodiment. A cycle counting circuit 2B according to the second embodiment includes the n-ary counter 22, the cycle counter 23, the remainder comparison circuit 24, a multiplexer (MUX) 31, a comparison register 32, and a comparison circuit 33.

The multiplexer 31 is a circuit that receives a plurality of inputs and outputs one result based on a selected input among the plurality of inputs. The multiplexer 31 includes k input terminals XI <k−1:0>, k input terminals YI <k−1:0>, k output terminals ZO <k−1:0>, and a select input terminal SELI2.

The multiplexer 31 receives a bit stream DF <n−1:n−k> at each of the input terminals XI <k−1:0>. The multiplexer 31 receives a bit stream DS <n−1:n−k> at each of the input terminals YI <k−1:0>. The multiplexer 31 outputs a bit stream DZ <k−1:0> at each of the output terminals ZO <k−1:0>.

The multiplexer 31 receives the signal DSEL at the select input terminal SELI2. The multiplexer 31 outputs the bit stream received at the input terminals XI <k−1:0> as the bit stream DZ <k−1:0> while the signal DSEL of the low level is being received. The multiplexer 31 outputs the bit stream received at the input terminals YI <k−1:0> as the bit stream DZ <k−1:0> while the signal DSEL of the high level is being received.

The comparison register 32 is a circuit that stores a bit stream input to the comparison register 32 based on the enable signal, and outputs the stored bit stream. The comparison register 32 can store a k-bit bit stream DB <k−1:0>. The comparison register 32 includes k input terminals ZI <k−1:0>, k output terminals BO <k−1:0>, an enable input terminal EI3, a clock input terminal CK5, and a reset signal input terminal RN5.

The comparison register 32 receives a bit stream DZ <k−1:0> at each of the input terminals ZI <k−1:0>. The comparison register 32 outputs a bit stream DB <k−1:0> at each of the output terminals BO <k−1:0>.

The comparison register 32 receives the reset signal RN at the reset signal input terminal RN5. When the reset signal RN of the low level is received, the comparison register 32 resets the stored bit stream to a predetermined initial value. The initial value of the comparison register 32 is set to the same value as the upper k bits (continuous k bits including the most significant bit) of the initial value of the register 11. In other words, a bit stream DS <n−1:n−k> stored in the register 11 and the bit stream DB <k−1:0> stored in the comparison register 32 are reset to the same value. The comparison register 32 operates while the reset signal RN of the high level is being received.

The comparison register 32 receives the clock CK at the clock input terminal CK5. The comparison register 32 receives an enable signal DE2 at the enable input terminal EI3.

An operation in an operation period of the comparison register 32, that is, a period where the reset signal RN of the high level is being received is as follows. When the enable signal DE2 of the high level is received in the operation period, the comparison register 32 stores the value of the bit stream DZ <k−1:0> in synchronization with the rising of the clock CK. When the enable signal DE2 of the low level is received in the operation period, the comparison register 32 does not change the value stored in the comparison register 32 without taking the value of the bit stream DZ <k−1:0> therein. The comparison register 32 outputs the value stored in the comparison register 32 as the bit stream DB <k−1:0> in the operation period irrespective of whether the value of the enable signal DE2 is the high level or the low level.

The comparison circuit 33 is a circuit that outputs a signal of a certain level when the values of the two input bit streams match each other. The comparison circuit 33 includes k input terminals AI <k−1:0>, k input terminals BI <k−1:0>, and an enable output terminal EO2.

The comparison circuit 33 receives a bit stream DF <r−1:r−k> at each of the input terminals AI <k−1:0>. The comparison circuit 33 receives a bit stream DB <k−1:0> at each of the input terminals BI <k−1:0>.

The comparison circuit 33 outputs the enable signal DE2 at the enable output terminal EO2. The comparison circuit 33 outputs the enable signal DE2 of the high level while the value of the bit stream received at the input terminals AI <k−1:0> and the value of the bit stream received at the input terminals BI <k−1:0> match each other. The comparison circuit 33 outputs the enable signal DE2 of the low level while the value of the bit stream received at the input terminals AI <k−1:0> and the value of the bit stream received at the input terminals BI <k−1:0> are different from each other.

The n-ary counter 22 receives the enable signal DE2 at the enable input terminal EI1. The cycle counter 23 receives the enable signal DE2 at the enable input terminal EI2.

### 2.2. Operation

When the number of cycles of the PRBS that is generated in parallel for every n bits is counted, the cycle of the PRBS cannot be detected for each time in the second type method, and 19 counting errors at a maximum occur in the example of FIG. 3. The reason for this is that the position of the first bit of the PRBS cycle in one word of the PRBS consisting of n bits is shifted for every cycle. The cycle counting circuit 2B is a counting circuit corresponding to the shift of the first bit in the second type method.

The cycle counting circuit 2B counts the number of cycles of the PRBS by comparing the bit stream DF <r−1:r−k> consisting of continuous k bits from the position based on the remainder r in the bit stream DF <n−1:0> from the feedback logic circuit 12 to a certain bit stream. The certain bit stream that is compared to the bit stream DF <r−1:r−k> is a fixed value in the first cycle counting, and subsequently is updated whenever the cycle is counted.

That is, the comparison circuit 33 compares the bit stream DF <r−1:r−k> received at the input terminals AI <k−1:0> to the bit stream DB <k−1:0> received at the input terminals BI <k−1:0>. When the bit stream DF <n−1:n−k> and the bit stream DB <k−1:0> match each other, the comparison circuit 33 outputs the enable signal DE2 of the high level. The rising edges of the enable signal DE2 are counted by the cycle counter 23 to count cycles of the PRBS. Hereinafter, the bit stream DF <r−1:r−k> will also be referred to as the comparison target bit stream, and the bit stream DB <k−1:0> will also be referred to as the reference bit stream.

The reference bit stream DB <k−1:0> is the output of the comparison register 32. The output of the comparison register 32 is reset to the initial value while the reset signal RN is at the low level. When the reset signal RN is at the high level, the output of the comparison register 32 is updated to the value of the bit stream DZ <k−1:0> output from the multiplexer 31 while the value of the enable signal DE2 from the comparison circuit 33 is at the high level. The updated value is different from the value before the update due to the properties of the PRBS. Therefore, the comparison result in the comparison circuit 33 is not a match, and the value of the enable signal DE2 is at the low level at a timing of the next rising of the clock CK. This way, the reference bit stream DB <k−1:0> is updated whenever the number of cycles is increased by 1.

As in the first embodiment, the cycle counting circuit 2B operates by dividing the number of times of counting by the number of bits n of one word of the PRBS and further dividing the number of times of n into a set containing the first counting to the r-th counting and a set containing the (r+1)th counting to the n-th counting. The cycle counting circuit 2B switches the value to be input to the comparison register 32 between the value of the set containing the first counting to the r-th counting and the value of the set containing the (r+1)th counting to the n-th counting. The selection of the value to be input to the comparison register 32 is performed by the multiplexer 31, and the selection by the multiplexer 31 is based on a signal DSEL from the remainder comparison circuit 24.

The cycle counting circuit 2B is reset by receiving the reset signal RN of the low level, and subsequently starts to operate by receiving the reset signal RN of the high level. At the start of the operation, the bit stream DU <j−1:0> that is the output of the n-ary counter 22 is reset to 0. Accordingly, the signal DSEL from the remainder comparison circuit 24 has a low level. The operation in the period where the signal DSEL has the low level is the operation in the period from the first counting to the r-th counting among the n cycle counting operations.

When the reset signal RN is at the low level, the value stored in the comparison register 32 is reset to the same value as the upper k bits of the bit stream stored in the register 11. This value is the initial value of the PRBS. When the reset signal RN is at the high level and the PRBS is sequentially generated such that one cycle of the PRBS is performed, the first bit of the PRBS appears at a position that is (r−k) bits more significant than the position of the first bit of the PRBS that is stored as the initial value in the register 11 when the reset signal RN is at the low level. The position of the first bit corresponds to a (r−k)th bit stream DF <r−k> in the bit stream DF <n−1:0>. Therefore, the bit stream DF <r−1:r−k> matches the reference bit stream (that is, the bit stream DB <k−1:0>) that is the initial value of the comparison register 32 at a timing of a clock cycle immediately before outputting one cycle of the PRBS from the PRBS generator circuit 1. Due to the match, the comparison circuit 33 outputs the enable signal DE2 of the high level. Accordingly, the rising edges of the enable signal DE2 are counted by the cycle counter 23 to count cycles of the PRBS.

When the number of matches between the comparison target bit stream and the reference bit stream in the comparison circuit 33 is less than r, the signal DSEL has the low level. Therefore, the multiplexer 31 selects the signal to be input from the input terminals XI <k−1:0>. Therefore, when the enable signal DE2 is at the high level due to the match between the comparison target bit stream and the reference bit stream, the comparison register 32 updates the storage content to the bit stream from the multiplexer 31, that is, the value of the bit stream DF <n−1:n−k> received at the input terminals XI <k−1:0> of the multiplexer 31 at a timing of the next rising of the clock CK. At this time, in the bit stream DF <n−1:n−k> stored in the comparison register 32 as the reference bit stream, the bit position in the output of the feedback logic circuit 12 is shifted forward in time by (n-r) bits relative to comparison target bit stream DF <r−1:r−k>.

In general, since the cycle of the PRBS is not a multiple of n, the comparison target bit stream and the reference bit stream match each other. Therefore, when another one cycle of the PRBS is performed, the value of the comparison target bit stream is different from the reference bit stream that is previously matched. Accordingly, when both of the comparison target bit stream and the reference bit stream match each other, the reference bit stream is rewritten with a value so that it may match the comparison target bit stream next time. As a method of rewriting the reference bit stream, there are two methods. One method is to rewrite the reference bit stream with a value that is more than one cycle of the PRBS and is shifted by a multiple of n bits closest to one full cycle. The other method is to rewrite the reference bit stream with a value that is less than one cycle of the PRBS and is shifted by a multiple of n bits closest to one full cycle. It is obvious from Expression 1 that, when one cycle of the PRBS is performed, the position of the first bit of the PRBS generated for every n bits is shifted forward in time by r bits from its original position. Accordingly, by selecting a bit stream at a position that is shifted by (n-r) bits forward in time relative to the comparison target bit stream, the reference bit stream can be rewritten with a value that is more than one cycle of the PRBS and is shifted by a multiple of n bits closest to one full cycle.

When the reference bit stream is rewritten, the comparison result in the comparison circuit 33 is not a match. Therefore, the value of the reference bit stream is stored until the next comparison result in the comparison circuit 33 is a match after the enable signal DE2 is at the low level. The above-described operation is repeated while the signal DSEL is at the low level, that is, until the comparison target bit stream matches the reference bit stream r times.

When the comparison target bit stream matches the reference bit stream r times, the signal DSEL is at the high level. Therefore, the multiplexer 31 selects the signal to be input from the input terminals YI <k−1:0>. Therefore, when the enable signal DE2 is at the high level due to the match between the comparison target bit stream and the reference bit stream, the comparison register 32 updates the storage content to the bit stream from the multiplexer 31, that is, the value of the bit stream DS <n−1:n−k> received at the input terminals YI <k−1:0> of the multiplexer 31 at a timing of the next rising of the clock CK. At this time, in the bit stream DS <n−1:n−k> stored in the comparison register 32 as the reference bit stream, the bit position spanning two words where the output of the feedback logic circuit 12 (serving as a high word) is concatenated with the output of the register 11 (serving as a low word) is shifted backward in time by r bits relative to the comparison target bit stream DF <r−1:r−k>.

When one cycle of the PRBS is performed, the position of the first bit of the PRBS generated for every n bits is shifted forward in time by r bits from its original position. Therefore, by selecting a bit stream at a position that is shifted backward in time by r bits relative to the comparison target bit stream, the reference bit stream can be rewritten with a value that is less than one cycle of the PRBS and is shifted by a multiple of n bits closest to one full cycle.

When the reference bit stream is rewritten, the comparison result in the comparison circuit 33 is not a match. Therefore, the value of the reference bit stream is stored until the next comparison result in the comparison circuit 33 is a match after the enable signal DE2 is at the low level. The above-described operation is repeated while the signal DSEL is at the high level.

While the n-ary counter 22 performs the counting n times, whenever the output of the cycle counter 23 is increased by one, the cycle counting circuit 2B updates the reference bit stream to the bit stream in the PRBS at a position that is shifted forward in time by (n-r) bits relative to the comparison target bit stream during the first r counting operations, and updates the reference bit stream to the bit stream in the PRBS at a position that is shifted backward in time by r bits relative to the comparison target bit stream during the next (n-r) counting operations. Accordingly, the cycle counting errors increase by (n-r) bits in the negative direction during the first r counting operations, and the cycle counting errors decrease by (n-r) bits in the positive direction during the next (n-r) counting operations. When the n cycle counting operations of the n-ary counter 22 ends, the cycle counting errors are represented by Expression 5 as in the first embodiment, and the value thereof is 0. At this time, the reference bit stream returns to the same value as the initial value of the comparison register 32. Therefore, even when the n-ary counter 22 performs the next n counting operations, the same operation is repeated, and the cycle counting of the PRBS is continuously performed.

### 2.3. Advantageous Effect

In the second embodiment, the number of cycles can be counted with smaller errors due to the same reason as that of the first embodiment.

In the second embodiment, the enable signal DE2 that functions as the cycle counting target is output based on the match between the comparison target bit stream and the reference bit stream. The reference bit stream is output from the comparison register 32, and the comparison register 32 updates the stored value only while the enable signal DE2 is at the high level. Therefore, the comparison register 32 does not need to count the clock CK to generate the enable signal DE2. Accordingly, the power consumption of the comparison register 32 is reduced, and a cycle counting circuit with reduced power consumption is implemented.

### 3. Third Embodiment

A third embodiment is common to the second embodiment in the method of detecting the cycle. The third embodiment relates to a case where the number of bits n is the power of 2.

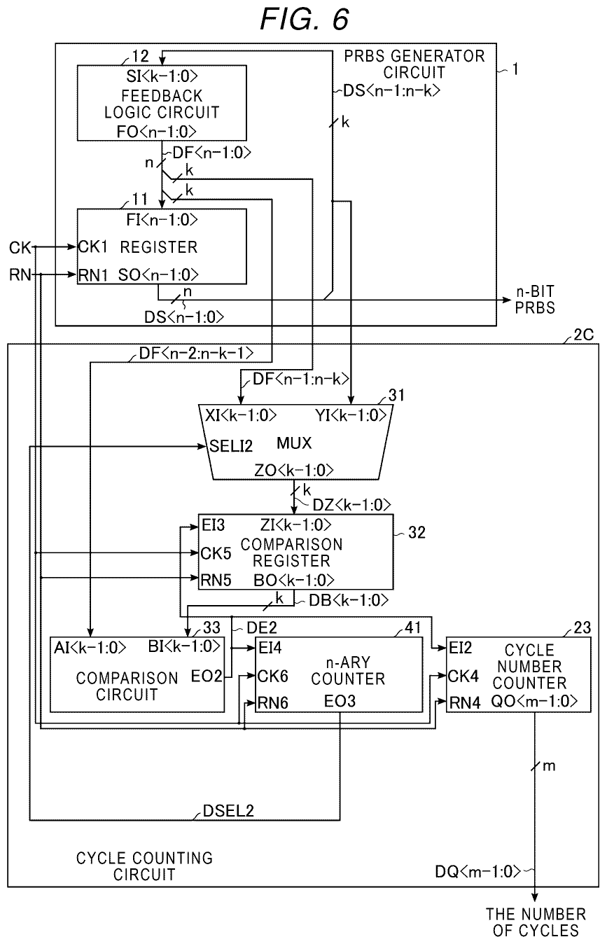

FIG. 6 is a block diagram illustrating a cycle counting circuit and a PRBS generator circuit according to the third embodiment. A cycle counting circuit 2C according to the third embodiment is similar to the cycle counting circuit 2B according to the second embodiment. The cycle counting circuit 2C includes the cycle counter 23, the multiplexer 31, the comparison register 32, and the comparison circuit 33, and does not include the remainder comparison circuit 24. The cycle counting circuit 2C includes an n-ary counter 41 without including the n-ary counter 22 according to the second embodiment.

The n-ary counter 41 is a circuit that counts edges of the supplied clock and outputs a signal having a level based on the count value. The n-ary counter 41 includes an enable input terminal EI4, a clock input terminal CK6, a reset signal input terminal RN6, and an output terminal EO3.

The n-ary counter 41 receives the enable signal DE2 at the enable input terminal EI4, and receives the clock CK at the clock input terminal CK6. The n-ary counter 41 counts rising edges of the clock CK only while the enable signal DE2 of the high level is being received. The n-ary counter 41 does not perform the counting while the enable signal DE2 of the low level is being received. The count value has any value of 0 or more and n−1 or less. When the count value reaches the upper limit (that is, n−1), the n-ary counter 41 resets the count value to 0 at a timing of the first rising of the clock CK in a period where the enable signal DE2 of the high level is being received after the count value reaches the upper limit. The n-ary counter 41 outputs a signal DSEL2 at the output terminal EO3. The n-ary counter 41 outputs the signal DSEL2 of the high level while the count value is n−1. The n-ary counter 41 outputs the signal DSEL2 of the low level while the count value is a value other than n−1.

The n-ary counter 41 receives the reset signal RN at the reset signal input terminal RN6. When the reset signal RN of the low level is received, the n-ary counter 41 resets the count value to 0. The n-ary counter 41 performs the counting while the reset signal RN of the high level is being received.

The comparison circuit 33 receives a bit stream DF <n−2:n−k−1> at each of the input terminals AI <k−1:0>.

The cycle of the PRBS is 2^{k}−1. Therefore, when 1 is added to the cycle of the PRBS, the obtained value is a power-of-2 number. In the third embodiment, n represents the power of 2. Therefore, the sum of the cycle of the PRBS and 1 is divided by n, and the remainder r is n−1. Therefore, the count value of the n-ary counter 41 is r or more only when the count value is n−1. Therefore, the n-ary counter 41 outputs the signal DSEL2 of the high level only while the count value is n−1. As a result, the state of the multiplexer 31 when the count value of the n-ary counter 41 is r or more, that is, the state where the bit stream DS <n−1:n−k> is selected is formed. Accordingly, when n is the power of 2, the cycle counting circuit 2C can count the number of cycles in the same form as that of the cycle counting circuit 2B according to the second embodiment. Therefore, the same advantageous effect as that of the second embodiment can be obtained with a simpler configuration than the cycle counting circuit 2B according to the second embodiment.

### 4. Fourth Embodiment

A fourth embodiment relates to a case where the same method of detecting the cycle as that of the third embodiment is used and the number of bits n represents the power of 2 as in the third embodiment. On the other hand, in the fourth embodiment, the same cycle detection as that of the third embodiment is implemented using another method.

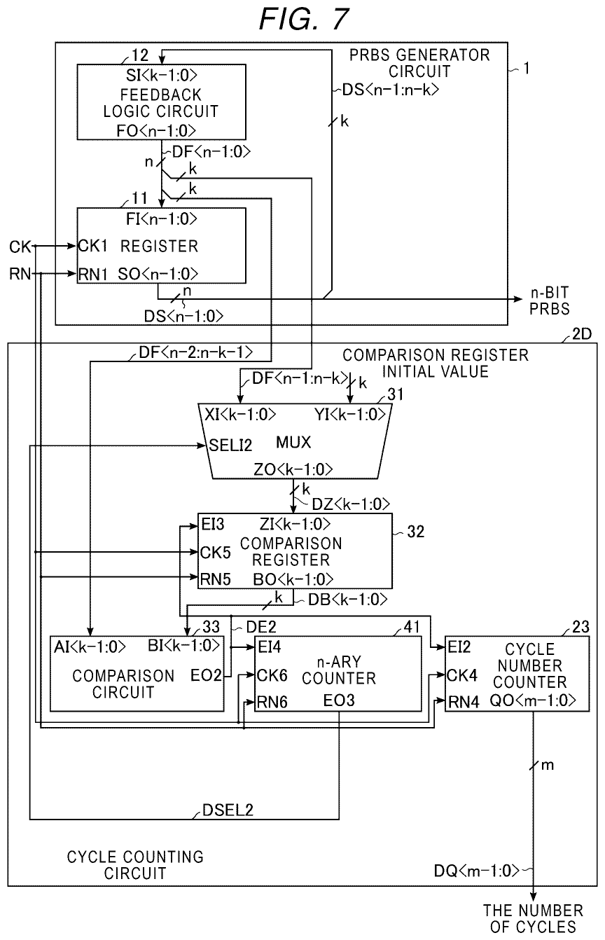

FIG. 7 is a block diagram illustrating a cycle counting circuit and a PRBS generator circuit according to the fourth embodiment. A cycle counting circuit 2D according to the fourth embodiment includes the same components as the cycle counting circuit 2C according to the third embodiment, that is, the cycle counter 23, the multiplexer 31, the comparison register 32, the comparison circuit 33, and the n-ary counter 41. On the other hand, the multiplexer 31 receives a comparison register initial value at the input terminals YI <k−1:0>. The comparison register initial value is a value that is stored in the comparison register 32 when the comparison register 32 receives the reset signal RN of the low level, and is a value in the bit stream DB <k−1:0>. For example, the comparison register initial value is supplied from the control circuit 3.

The continuous k bits including the most significant bit in the value stored in the register 11, that is, the initial value of the bit stream DS <n−1:n−k> is the same as the value stored in the comparison register 32, that is, the initial value of the bit stream DB <k−1:0>. When the n-ary counter 41 performs the counting n times such that the count value returns to 0, the value stored in the register 11, that is, the bit stream DS <n−1:n−k> returns to the initial value. Therefore, when the n-ary counter 41 performs the counting n times to output the signal DSEL2 of the high level, the comparison register initial value is selected by the multiplexer 31 based on the signal DSEL2 of the high level. As a result, when the clock CK rises, the value stored in the comparison register 32 is reset to the initial value. That is, when the bit stream DS <n−1:n−k> is supplied to the input terminals YI <k−1:0> of the multiplexer 31 as in the third embodiment, the same operation as the operation of supplying the bit stream DS <n−1:n−k> of the initial value of the register 11 to the comparison register 32 is performed for every n cycle counting operations. Therefore, in the fourth embodiment, the same advantageous effect as that of the third embodiment can be obtained.

A set containing the multiplexer 31 that receives the initial value of the comparison register 32 at the input terminals YI <k−1:0> and the comparison register 32 can be considered a register with the synchronous reset where the select input terminal SELI2 of the multiplexer 31 is used as a synchronous reset input terminal. Accordingly, the set including the multiplexer 31 that receives the initial value of the comparison register 32 at the input terminals YI <k−1:0> and the comparison register 32 may be implemented by an integrated circuit as a register with the synchronous reset where the select input terminal SELI2 of the multiplexer 31 is used as a synchronous reset input terminal.

### 5. Fifth Embodiment

A fifth embodiment is common to the second embodiment in the method of detecting the cycle. The fifth embodiment relates to a case where the remainder r is less than the order k.

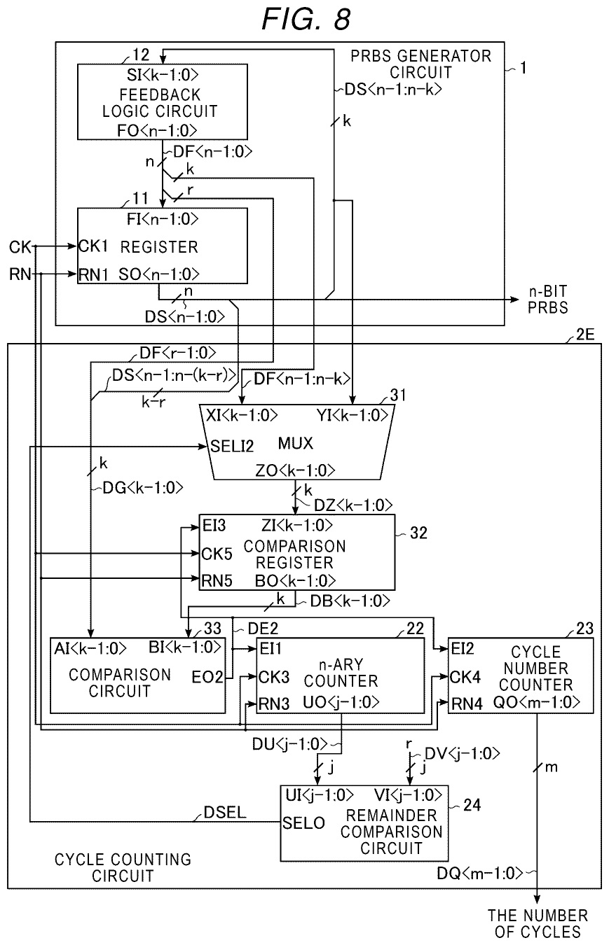

FIG. 8 is a block diagram illustrating a cycle counting circuit and a PRBS generator circuit according to the fifth embodiment. A cycle counting circuit 2E according to the fifth embodiment includes the same components as the cycle counting circuit 2B according to the second embodiment. On the other hand, some components receive bit streams different from those of the second embodiment.

The comparison circuit 33 receives a bit stream DG <k−1:0> at each of the input terminals AI <k−1:0>. The bit stream DG <k−1:0> includes a bit stream DF <r−1:0> in continuous r bits including the most significant bit, and includes a bit stream DS <n−1:n-(k-r)> in the remaining continuous (k-r) bits including the least significant bit. That is, the bit stream DG <k−1:0> includes lower r bits of the bit stream DF <n−1:0> in the (k−1)th to the (k-r)th bits, respectively, and includes upper (k-r) bits of the bit stream DS <n−1:0> in the (k-r-1)th to the 0th bits, respectively.

In the fifth embodiment, when the remainder r is less than the order k, the cycle counter 23, the multiplexer 31, the comparison register 32, the comparison circuit 33, and the n-ary counter 22 operate as in the second embodiment. Accordingly, when the remainder r is less than the order k, the same advantageous effect as that of the second embodiment can be obtained.

### 6. Sixth Embodiment

A sixth embodiment is common to the second embodiment in the method of detecting the cycle. The sixth embodiment relates to a case where the remainder r is greater than or equal to the order k of the PRBS.

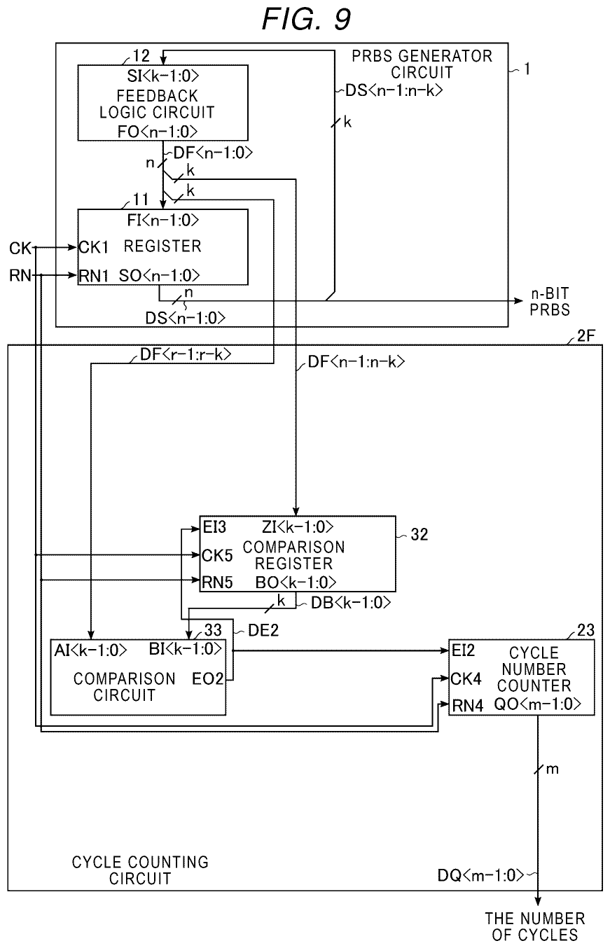

FIG. 9 is a block diagram illustrating a cycle counting circuit and a PRBS generator circuit according to the sixth embodiment. A cycle counting circuit 2F according to the sixth embodiment includes the cycle counter 23, the comparison register 32, and the comparison circuit 33. On the other hand, some components receive bit streams different from those of the second embodiment.

The comparison register 32 receives a bit stream DF <n−1:n−k> at each of the input terminals ZI <k−1:0>.

In FIG. 4, there is no difference between the cycle count value in the first type method and the cycle count value in the first embodiment for a certain period from the start of counting. In particular, when the number of bits n is the power of 2, the number of bits of the PRBS required for increasing the cycle count value by one is different only by one bit from one cycle of the PRBS. Therefore, the cycle count value in the first embodiment is not different from the cycle count value in the first type method until the counting is performed (n−1) times from the start of counting. Based on this configuration, the sixth embodiment does not include the multiplexer 31, the n-ary counter 22, and the remainder comparison circuit 24 that function to reduce errors in the second embodiment. As a result, according to the sixth embodiment, the cycle counting circuit 2F is implemented, in which, when the upper limit of the number of cycles to be counted is small, only reduced errors occur in the cycle count value as in the second embodiment, and the power consumption is further reduced as compared to the second embodiment.

### 7. Seventh Embodiment

A seventh embodiment is common to the second embodiment in the method of detecting the cycle. The seventh embodiment relates to a case where the remainder r is less than the order k of the PRBS as in the fifth embodiment.

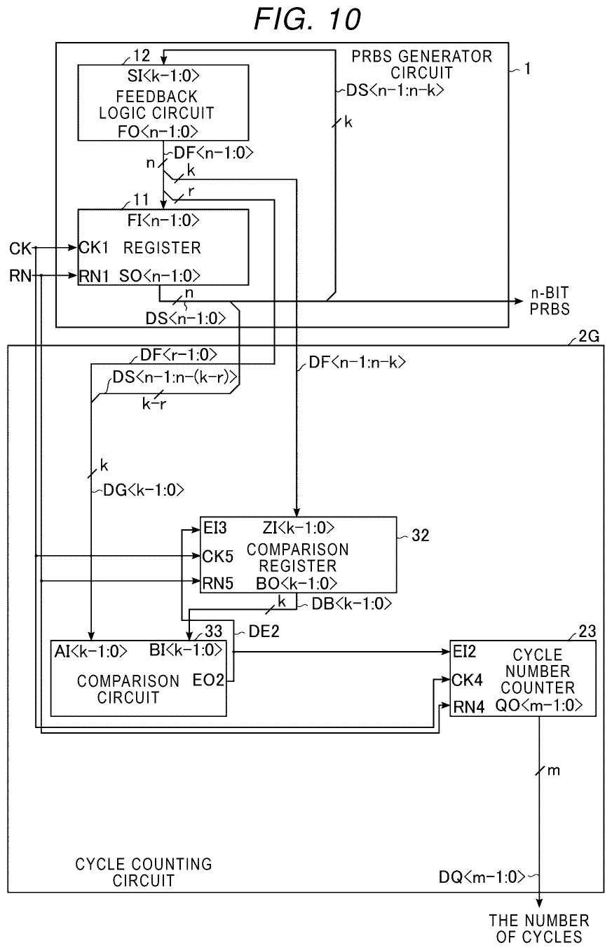

FIG. 10 is a block diagram illustrating a cycle counting circuit and a PRBS generator circuit according to the seventh embodiment. A cycle counting circuit 2G according to the seventh embodiment includes the same components as the cycle counting circuit 2F according to the sixth embodiment. On the other hand, some components receive bit streams different from those of the sixth embodiment.

The comparison register 32 receives a bit stream DF <n−1:n−k> at each of the input terminals ZI <k−1:0> as in the sixth embodiment.

The comparison circuit 33 receives a bit stream DG <k−1:0> at each of the input terminals AI <k−1:0> as in the fifth embodiment.

In the seventh embodiment, when the remainder r is less than the order k, the cycle counter 23, the comparison register 32, and the comparison circuit 33 operate as in the sixth embodiment. Accordingly, when the remainder r is less than the order k, the same advantageous effect as that of the sixth embodiment can be obtained. Further, according to the seventh embodiment, the cycle counting circuit 2F is implemented, in which, when the upper limit of the number of cycles to be counted is small, only reduced errors occur in the cycle count value as in the fifth embodiment, and the power consumption is further reduced as compared to the fifth embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A cycle counting circuit for counting the number of cycles of a bit stream that has a cycle of 2^{k}−1 bits (where k is a positive integer) bits, and is output in units of n bits (where n is a positive integer) in synchronization with a clock, the cycle counting circuit comprising:
a first counter configured to operate as a (p+1)-ary counter (where p is a quotient of a division in which 2^{k}−1 is a dividend and n is a divisor) while a selection signal of a first level is being received, to operate as a p-ary counter while the selection signal of a second level is being received, to count clock cycles to acquire a first count value, and to output a first signal of a third level when the first count value reaches p while the first counter is operating as the (p+1)-ary counter and when the first count value reaches p−1 while the first counter is operating as the p-ary counter;
a second counter configured to count occurrences of the first signal at the third level to acquire a second count value and to output a first bit stream representing the second count value;
an n-ary counter configured to count occurrences of the first signal at the third level to acquire a third count value and to output a second bit stream representing the third count value; and
a comparison circuit configured to output the selection signal of the first level while the third count value is less than r (where r is a remainder of the division) and to output the selection signal of the second level while the third count value is r or more.

2. The cycle counting circuit according to claim 1, wherein
the n-ary counter is configured to set the third count value to 0 when the first signal at the third level is received while the third count value is n−1.

3. A cycle counting circuit for counting the number of cycles of an output bit stream that has a cycle of 2^{k}−1 bits (where k is a positive integer), and is output in units of n bits (where n is a positive integer),
the generator circuit including:
a first register configured to receive a first bit stream, to store the first bit stream, and to output the first bit stream as the output bit stream based on a clock, and
a logic circuit configured to generate the first bit stream through a logical operation on a second bit stream that consists of continuous k bits including a most significant bit of the output bit stream, and
the cycle counting circuit comprising:
a multiplexer configured to output, as a fourth bit stream, a third bit stream that consists of continuous k bits including a most significant bit of the first bit stream while a selection signal of a first level is being received and to output the second bit stream as the fourth bit stream while the selection signal of a second level is being received;
a second register configured to store the fourth bit stream and to output the fourth bit stream as a fifth bit stream while a first signal of a third level is being received and to output the fifth bit stream without storing the fourth bit stream while the first signal of a fourth level is being received;
a first comparison circuit configured to output the first signal of the third level when a sixth bit stream that consists of continuous k bits from a (r−1)th bit to a (r−k)th bit (where r is a remainder of a division where 2^{k}−1 is a dividend and n is a divisor) of the first bit stream matches the fifth bit stream;
a first counter configured to count occurrences of the first signal at the third level to acquire a first count value and to output a seventh bit stream representing the first count value;
an n-ary counter configured to count occurrences of the first signal at the third level to acquire a second count value and to output an eighth bit stream representing the second count value; and
a second comparison circuit configured to output the selection signal of the first level while the second count value is less than r and to output the selection signal of the second level while the second count value is r or more.

4. The cycle counting circuit according to claim 3, wherein
when a reset signal of a fifth level is received, continuous k bits including a most significant bit of the first register and the second register are reset to the same value.

5. The cycle counting circuit according to claim 4, wherein
when the clock that changes from a sixth level to a seventh level is received while the first signal of the third level is being received, the second register stores the third bit stream therein and outputs a value of the third bit stream as the fifth bit stream, and when the clock that changes from the sixth level to the seventh level is received while the first signal of the fourth level is being received, the second register outputs a value stored therein as the fifth bit stream without storing the third bit stream therein.

6. The cycle counting circuit according to claim 3, wherein
the n-ary counter is configured to set the second count value to 0 when the first signal of the third level is received while the second count value is n−1.

7. A cycle counting circuit for counting the number of cycles of an output bit stream that has a cycle of 2^{k}−1 bits (where k is a positive integer), and is output in units of n bits (where n is a positive integer),
the generator circuit including:
a first register configured to receive a first bit stream, to store the first bit stream, and to output the first bit stream as the output bit stream based on a clock, and
a logic circuit configured to generate the first bit stream through a logical operation on a second bit stream that consists of continuous k bits including a most significant bit of the output bit stream, and
the cycle counting circuit comprising:
a multiplexer configured to output, as a fourth bit stream, a third bit stream that consists of continuous k bits including a most significant bit of the first bit stream while a selection signal of a first level is being received and to output the second bit stream as the fourth bit stream while the selection signal of a second level is being received;
a second register configured to store the fourth bit stream and to output the fourth bit stream as a fifth bit stream while a first signal of a third level is being received and to output the fifth bit stream without storing the fourth bit stream while the first signal of a fourth level is being received;
a comparison circuit configured to output the first signal of the third level when a sixth bit stream that consists of continuous k bits from a (n−2)th bit to a (n−k-1)th bit of the first bit stream matches the fifth bit stream;
a first counter configured to count occurrences of the first signal at the third level to acquire a first count value and to output a seventh bit stream representing the first count value; and
an n-ary counter configured to count occurrences of the first signal at the third level to acquire a second count value, to output the selection signal of the second level while the second count value is n−1, and to output the selection signal of the first level while the second count value is a value other than n−1.

8. The cycle counting circuit according to claim 7, wherein
when the clock that changes from a fifth level to a sixth level is received while the first signal of the third level is being received, the second register stores the fourth bit stream therein and outputs a value of the taken fourth bit stream as the fifth bit stream, and when the clock that changes from the fifth level to the sixth level is received while the first signal of the fourth level is being received, the second register outputs a value stored therein as the fifth bit stream without storing the fourth bit stream therein.

9. The cycle counting circuit according to claim 7, wherein
the n-ary counter is configured to set the second count value to 0 when the first signal of the third level is received while the second count value is n−1.
